(19) United States
(12) Patent Application Publication
(10) Pub. No.: US 2025/0157828 A1
(43) Pub. Date: May 15, 2025

(54) SEMICONDUCTOR ASSEMBLIES WITH UNDERFILL SQUEEZE-UP, AND METHODS FOR MAKING THE SAME

(71) Applicant: Micron Technology, Inc., Boise, ID (US)

(72) Inventors: Youngrae Kim, Taichung (TW); Ying-Ta Chiu, Taichung (TW); Wei Hung Tang, Taichung (TW)

(21) Appl. No.: 18/896,782

(22) Filed: Sep. 25, 2024

Related U.S. Application Data
(60) Provisional application No. 63/598,479, filed on Nov. 13, 2023.

(51) Int. Cl. H01L 21/56; H01L 23/31; H01L 25/00; H01L 25/065

(52) U.S. Cl. CPC H01L 21/563; H01L 21/568; H01L 23/3185; H01L 25/0657; H01L 25/50; H01L 2225/06586

(57) ABSTRACT

A semiconductor device assembly is provided. The assembly includes a substrate and a stack of semiconductor devices. The stack of semiconductor devices includes core semiconductor devices and a top semiconductor device disposed at the top of the stack. Each core device has a first thickness. The top device has a second thickness that is greater than the first thickness. Every device in the stack has a gap beneath it, with underfill material filling every gap and covering the sides of the core semiconductor devices. The underfill material has a squeeze-out region protruding away from the stack a first distance, and a squeeze-up region extending up the top semiconductor device a second distance. The second distance measures at least the same as the height of the gap beneath the devices in the stack.

### CROSS-REFERENCE TO RELATED APPLICATION(S)

The present application claims priority to U.S. Provisional Patent Application No. 63/598,479, filed Nov. 13, 2023, the disclosure of which is incorporated herein by reference in its entirety.

### TECHNICAL FIELD

The present disclosure generally relates to semiconductor device assemblies, and more particularly relates to semiconductor assemblies with underfill squeeze-up, and methods for making the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a partial cross-sectional view of an example semiconductor device assembly with underfill.

FIG. 2 is a partial cross-sectional view of a semiconductor device assembly in accordance with embodiments of the present technology.

FIGS. 3A-3D are simplified cross-sectional views illustrating a series of fabrication steps of semiconductor device assemblies in accordance with an embodiment of the present technology.

FIG. 4 is a schematic view showing a system that includes a semiconductor device assembly configured in accordance with an embodiment of the present technology.

FIG. 5 is a flow chart illustrating a method of making a semiconductor device assembly in accordance with an embodiment of the present technology.

### DETAILED DESCRIPTION

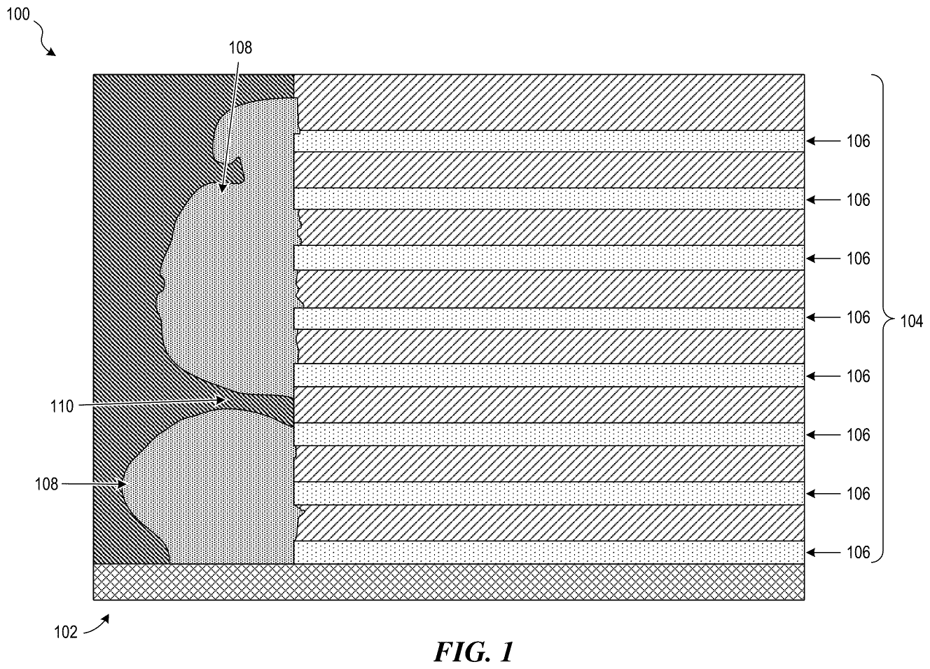

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc. One approach to accommodate the packaging of such varied devices into a single assembly is to form electrical connections between a semiconductor device and a semiconductor substrate, connections which may include solder bumps and copper pillar interconnections. However, the problem with such connections is in the mismatch in the coefficient of thermal expansion (CTE) between the semiconductor device, which may be made of a silicon material, and the substrate, which may be made of a polymer-based material. Underfill material can stabilize the connections between a semiconductor device and a substrate. An example of a semiconductor assembly with underfill material is illustrated in FIG. 1.

As can be seen with reference to FIG. 1, the semiconductor device can include a stack of semiconductor devices 104, in which each device has a layer of underfill material 106 disposed beneath it. The underfill material 106 can stabilize the connections between devices as well as between the bottommost device and a substrate 102. This stability is important as the assembly 100 experiences dramatic temperature fluctuations throughout the packaging process. Underfill material 106 can include a Non-Conductive Film (NCF). NCF can enable the underfill material to be pre-applied to the semiconductor device before attaching the device to the substrate, which avoids the problems of previous underfill material, including flux residues and air gaps between fine-pitch interconnections. NCF, however, have its challenges. One challenge is excessive squeeze-out 108, in which a large quantity of underfill material 106 is squeezed out from under and between the stack of devices 104 due to the forces imposed on the stack from thermocompression bonding. Due to the viscosity of the underfill material 106, void traps 110 can also form between the excessive squeeze-out 108. These features add greater mechanical stress to the assembly 100 and make it more prone to forming cracks. A crack can impair, or entirely prevent, an assembly of semiconductor devices from performing as designed, manifesting in electrical defects (e.g., intermittent contact, variable resistance, loss of capacitance, excessive leakage currents, etc.).

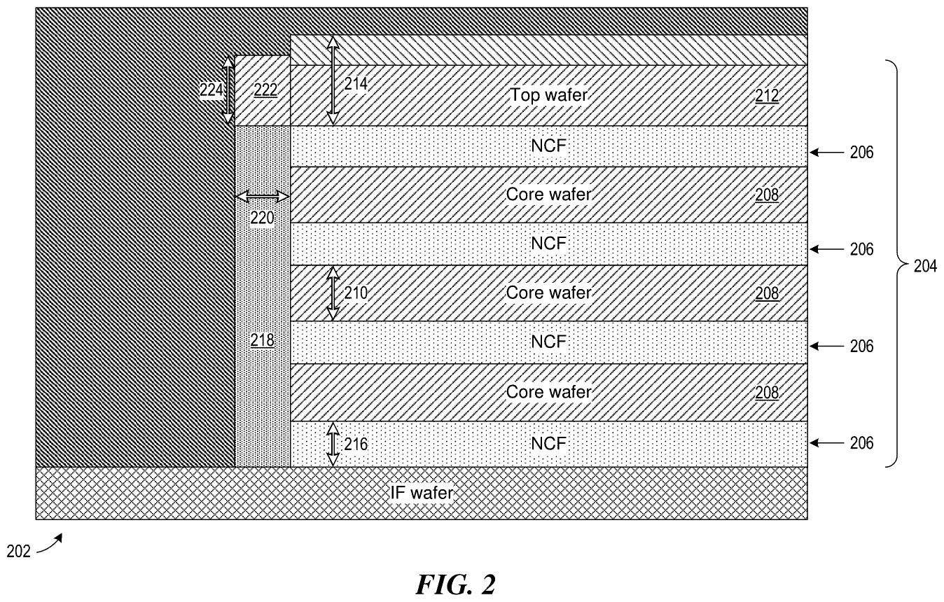

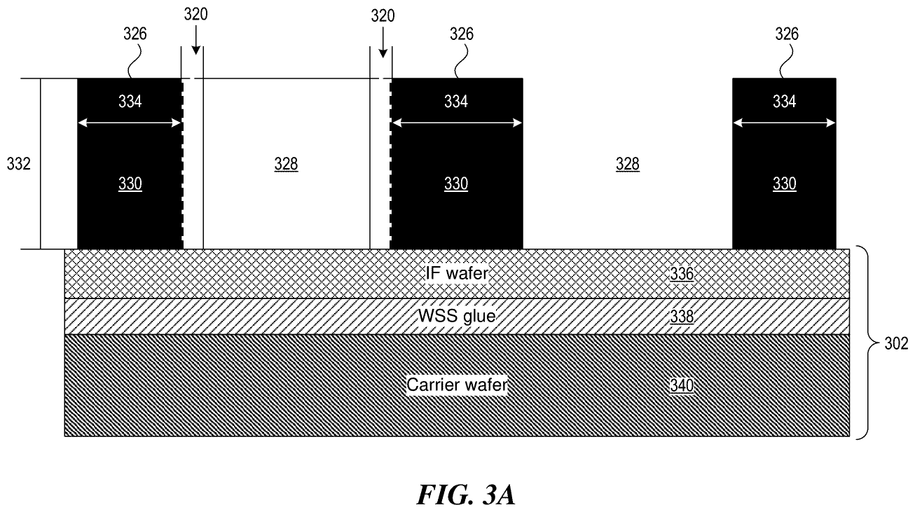

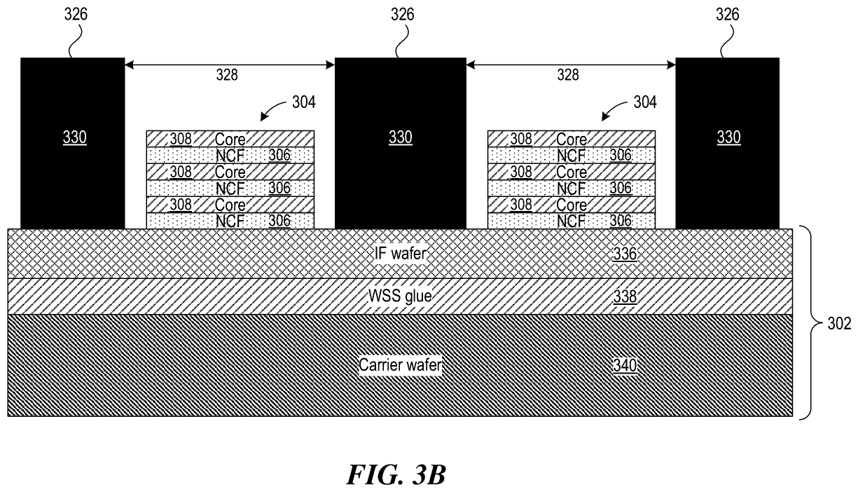

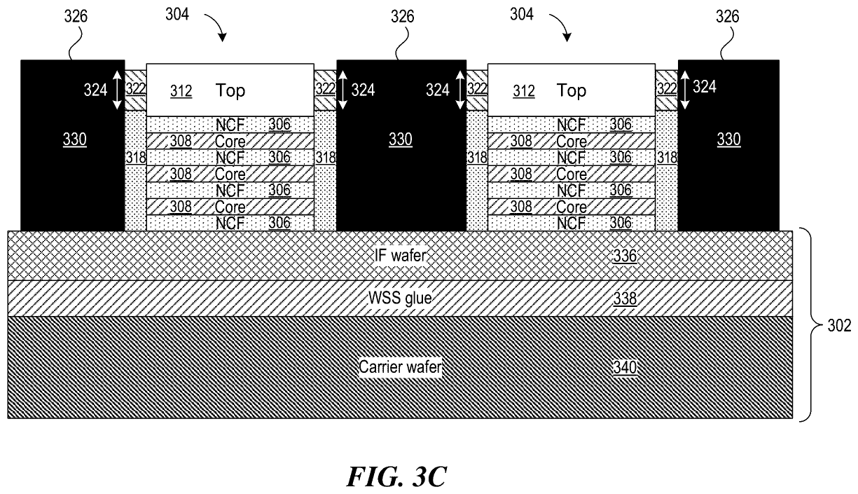

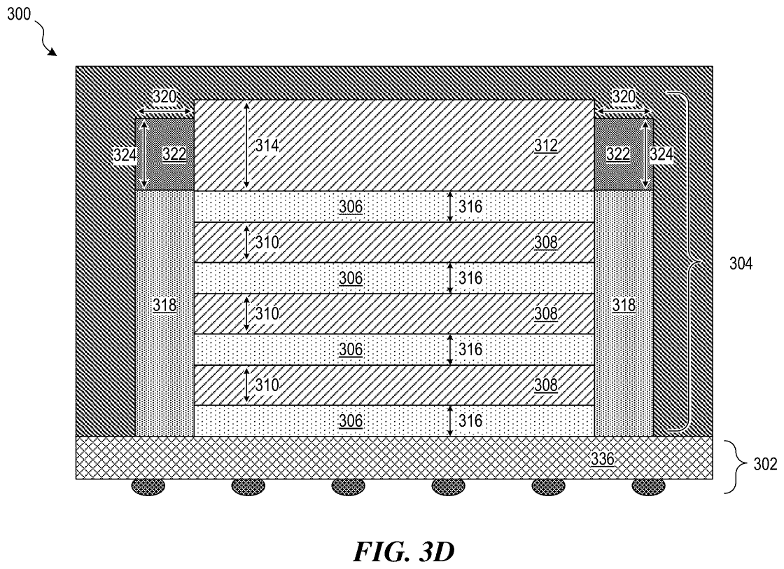

To address these drawbacks and others, various embodiments of the present disclosure provide semiconductor assemblies with underfill squeeze-up, and methods for making the same. FIG. 2 is a partial cross-sectional view of a semiconductor device assembly 200 in accordance with embodiments of the present technology. The semiconductor device assembly 200 includes a substrate 202 and a stack of semiconductor devices 204. The substrate 202 can include a layer of Silicon Nitride and a layer of Silicon below the layer of Silicon Nitride. Additionally, or alternatively, the substrate 202 can include a first layer, illustrated in later figures, the first layer including an interface wafer, an interface die, a logic die, or a memory controller. The stack 204 includes core semiconductor devices 208, wherein each core device has a first thickness 210, and a top semiconductor device 212 disposed at a top of the stack 204, wherein the top device has a second thickness 214 that is greater than the first thickness 210. The stack 204 further includes a gap beneath every core device 208 and the top device 212. Each gap has a height 216, with underfill material 206 filling every gap and encompassing the core semiconductor devices 208. The underfill material 206 has a squeeze-out region 218 and a squeeze-up region 222. The underfill material 206 can include sides that are planar. These regions have been distinguished in the Figures to call attention to them as distinct areas of a contiguous material. That is, in physical embodiments, the squeeze-out region 218 and the squeeze-up region 222 may appear as a part of the same underfill material 206. The underfill material 206 can include a non-conductive film (NCF). The squeeze-out region 218 protrudes away from the stack 204 a first distance 220 and the squeeze-up region 222 extends up the top semiconductor device 212 a second distance 224. The second distance 224 can measure at least the same as the height 216 of the gap. The first distance 220 of the squeeze-out 218 can measure up to 50 micrometers. Alternatively, the first distance 220 can measure 200, 150, or 100 micrometers. The second distance 224 of the squeeze-up 222 can measure up to the second thickness 214 of the top semiconductor device 212. These regions of underfill material assist the assembly 200 in overcoming the challenges illustrated by the assembly 100 from FIG. 1, which are exemplified by excessive squeeze-out 108 and void traps 110. An example method which provides these features, among others, to the assembly 200 are illustrated in FIGS. 3A-3D. as a series of fabrication steps of an example semiconductor device assembly 300, in accordance with embodiments of the present technology.

FIG. 3A illustrates a fabrication step for providing a substrate 302 and disposing a template 326 on the substrate 302 in a simplified cross-sectional view. The substrate 202 can include a layer of Silicon Nitride and a layer of Silicon below the layer of Silicon Nitride. Additionally, or alternatively, the substrate 202 can include a first layer 336, the first layer 336 including an interface wafer an interface die, a logic die, or a memory controller. Additionally, below the first layer 336 can be a layer of adhesive 338, and a carrier wafer 340 can be disposed below the layer of adhesive 338.

The template 326 includes an opening 328 surrounded by walls 330. Disposing a template 326 on the substrate 302 can include photolithography. In such an implementation of the method, the template 326 can include a photoresist material. Alternatively, in other implementations, the template 326 can include a metal or a rubber material. Additional methods of disposing a template 326 on the substrate 302 can include spraying, screen printing, or inkjet printing. The template walls 330 have a wall height 332. The wall height 332 can measure up to 5 mm. The template walls have a wall width 334. The wall width can measure about 1 um up to about 900 um. The template walls 330 can have a Young's Modulus of at least 2.0 GPa, to assist them in containing an underfill material undergoing changes in viscosity due to temperature fluctuations. Additionally, contained within the opening 328 is a gap 320, as illustrated in FIG. 3A, which will contain a squeeze-out region and a squeeze-up region of underfill material.

Alternatively, in the step illustrated by FIG. 3A, the substrate 302 can be a semiconductor wafer 302. In such an alternative implementation, the step can further include coating the wafer 302 with a photoresist material and spinning the wafer 302 until the photoresist material forms a thick photoresist layer on the wafer 302, before exposing areas of the thick photoresist layer to ultraviolet light. The wafer can be spun at a speed less than 3000 rpm, and the thick layer of photoresist material can measure at least 100 um or up to 2 mm. This implementation can then include developing the exposed areas of photoresist to leave behind a photoresist lattice structure 326 on the wafer 302, the lattice structure 326 having openings 328 with walls 330 that interconnect.

FIG. 3B illustrates a fabrication step for disposing a stack of core semiconductor devices 304 within the opening 328 of the template 326, in a simplified cross-sectional view. In such an implementation, each core semiconductor device 308 in the stack 304 has a layer of underfill material 306 beneath it. This step can further include a top semiconductor device 312, as illustrated in FIG. 3C, which also has a layer of underfill material 306 beneath it. The underfill material 306 can include a non-conductive film (NCF). The top device 312, along with the underfill 306, can be disposed atop the stack of core semiconductor devices 304. Each layer of underfill material 306 has a thickness 316, as illustrated in FIG. 3D. Also as illustrated in FIG. 3D, each core device has a first thickness 310, and the top device has a height 314 that is greater than the first thickness 310. One alternative implementation of this step can include disposing a semiconductor device within the opening 328 of the template 326, in place of the stack 304. Each layer of underfill material 306 has a thickness 316, as illustrated in FIG. 3D.

In alternative implementations in which the substrate is a wafer 302 and the template is a photoresist lattice structure 326, disposing a stack of semiconductor devices can include disposing a stack 304 inside every opening 328 within the lattice 326 such that each stack is surrounded by the walls 330, as illustrated in FIG. 3B. Each stack 304 includes a top semiconductor 312 device at the top of the stack, and each device included within each stack 304 has an underfill material 306 disposed in a gap underneath it, wherein the gap has a thickness 316 (as illustrated in FIG. 3D). Additionally, each stack 304 has a first height and the lattice structure 326 has a second height, such that the first height is less than or equal to the second height.

In a simplified cross-sectional view, FIG. 3C illustrates a fabrication step for bonding the stack 304 and causing each layer of underfill material to bulge beyond the device above it until making contact with the walls 330 of the template 326, such that the layers of underfill material 306 run together to form an underfill encasement 318 and a squeeze-up region 322. These regions have been distinguished in the Figures to call attention to them as distinct areas of a contiguous substance. The underfill encasement 318 surrounds the stack of core devices 304 and the squeeze-up region 322 runs up the device a height 324. The height 324 of the squeeze-up region 322 can measure between the thickness 316 of the underfill material 306 and the height 314 belonging to the top semiconductor device 312. The underfill material 306 pressing against the walls 330 of the template 326 can cause the underfill encasement 318 and squeeze-up region 322 to have even sidewalls. One alternative implementation of this step can include replacing the stack 304 with a semiconductor device. In such case an implementation, the device is bonded, causing the underfill material 306 to extrude away from the device such that the underfill material 306 presses against the walls 330 of the template 326 and forms a squeeze-out region 318 and a squeeze-up region 322. The squeeze-up region 322 runs up the device a height 324. The underfill material 306 pressing against the walls 330 of the template 326 can cause the squeeze-out region 318 and the squeeze-up region 322 to have even sidewalls. The height 324 of the squeeze-up region 322 can measure between the thickness 316 of the underfill material 306 and a height 314 belonging to the semiconductor device 312. The squeeze-up region has a width 320, as illustrated in FIG. 3D. The width 320 can measure up to 50 micrometers, or it can measure 200, 150, or 100 micrometers.

In alternative implementations, in which the substrate is a wafer 302 and the template is a photoresist lattice structure 326, bonding the stack can include pressing down on the top device 312 of every stack 304 on the wafer 302 while increasing the temperature. This step causes the underfill material 306 to squeeze out from each stack 304 to form an underfill coating 318 around each stack 304, with a squeeze-up region 322 that reaches a distance 324 up the top device 312. The underfill coating has a width 320, as illustrated in FIG. 3D, and the width can measure up to 50 micrometers, or 200, 150, or 100 micrometers.

FIG. 3D illustrates a fabrication step in which the underfill material 306 has been cured and the template 326 has been removed, in a simplified cross-sectional view. Curing the underfill material 306 can include curing the layers of underfill material 306, the underfill encasement 318, and the squeeze-up region 322. Alternatively, curing the underfill material 306 can include curing the layers of underfill material 306, the squeeze-out region 318, and the squeeze-up region 322. Additionally, this method can include removing the layer of adhesive 338 and the carrier wafer 340 from the substrate 302, leaving behind just the first layer 336 (e.g., a memory die). In certain implementations, the method can further include separating the stack 304 from adjacent stacks of semiconductor devices, forming an individuated semiconductor assembly 300 with underfill squeeze-up 322.

In alternative implementations, in which the substrate is a wafer 302 and the template is a photoresist lattice structure 326, curing the underfill material can include curing the underfill coating. In such implementations, removing the template includes stripping the photoresist lattice structure 326 from the wafer 302 and splitting apart the wafer 302 to form an individual semiconductor device assembly 300, the assembly 300 including a hardened underfill coating 318 with a squeeze-up region 322. The foregoing methods can further include encapsulating such assemblies in an encapsulant material and providing the substrate 302 with external electrical connections, for example, solder balls, as illustrated in FIG. 3D.

Although in the foregoing example embodiment semiconductor device assemblies have been illustrated and described as including a single semiconductor device, in other embodiments assemblies can be provided with additional semiconductor devices. For example, the single semiconductor devices illustrated in the Figures could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 2-3D could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

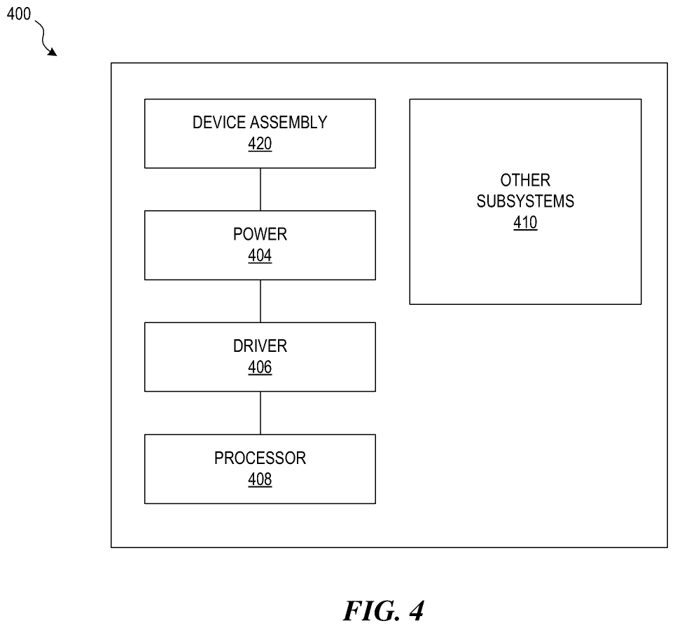

Any one of the semiconductor devices and semiconductor device assemblies described above with reference to FIGS. 2-3D can be incorporated into any of a myriad of larger and/or more complex systems, a representative example of which is system 400 shown schematically in FIG. 4. The system 400 can include a semiconductor device assembly 402 (e.g., or a discrete semiconductor device), a power source 404, a driver 406, a processor 408, and/or other subsystems or components 410. The semiconductor device assembly 402 can include features generally similar to those of the semiconductor devices described above with reference to FIGS. 2-3D. The resulting system 400 can perform any of a wide variety of functions, such as memory storage, data processing, and/or other suitable functions. Accordingly, representative systems 400 can include, without limitation, hand-held devices (e.g., mobile phones, tablets, digital readers, and digital audio players), computers, vehicles, appliances and other products. Components of the system 400 may be housed in a single unit or distributed over multiple, interconnected units (e.g., through a communications network). The components of the system 400 can also include remote devices and any of a wide variety of computer readable media.

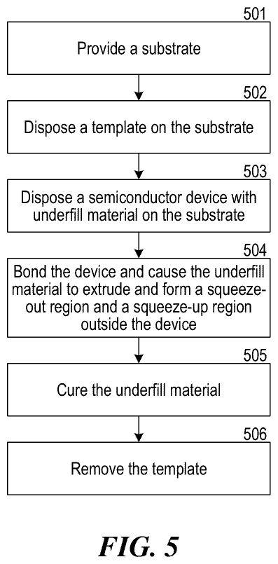

FIG. 5 is a flow chart illustrating a method of making a semiconductor device assembly. The method includes providing a substrate (box 501). The method further includes disposing a template on the substrate (box 503). The method further includes disposing a semiconductor device with underfill material beneath it on the substrate, inside an opening formed by the template (box 505). The method further includes bonding the device and causing the underfill material to extrude and form a squeeze-out region and a squeeze-up region outside the device (box 507). The method further includes curing the underfill material (box 509). The method further includes removing the template to form a semiconductor assembly with a squeeze-up region of underfill material (box 511).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate; and
a stack of semiconductor devices, including:
one or more core semiconductor devices, wherein each core semiconductor device has a first thickness,
a top semiconductor device disposed at a top of the stack, wherein the top semiconductor device has a second thickness that is greater than the first thickness,
a gap beneath every semiconductor device in the stack, wherein each gap has a height,
underfill material filling every gap and encompassing the core semiconductor devices, the underfill material having:
a squeeze-out region, the squeeze-out region protruding away from the stack a first distance,
a squeeze-up region, the squeeze-up region extending up the top semiconductor device a second distance, wherein the second distance measures at least as much as the height of the gap.

2. The semiconductor device assembly of claim 1, wherein the underfill material includes exterior sides that are substantially planar.

3. The semiconductor device assembly of claim 1, wherein the first distance of the squeeze-out measures up to 200 μm.

4. The semiconductor device assembly of claim 1, wherein the second distance of the squeeze-up is less than or equal to the second thickness of the top semiconductor device.

5. The semiconductor device assembly of claim 1, wherein the substrate comprises a layer of silicon nitride disposed over a layer of silicon.

6. The semiconductor device assembly of claim 1, wherein the substrate comprises an interface wafer, an interface die, a logic die, or a memory controller.

7. The semiconductor device assembly of claim 1, wherein the underfill material comprises a non-conductive film (NCF).

8. A method of making a semiconductor device assembly, the method comprising:
providing a substrate;
disposing a template on the substrate, the template including an opening defined by sidewalls;
disposing a semiconductor device and an underfill material within the opening of the template, wherein the underfill material is under the semiconductor device and has a thickness;
bonding the semiconductor device to the substrate, causing the underfill material to extrude away from the semiconductor device such that the underfill material presses against the walls of the template and forms a squeeze-out region and a squeeze-up region, the squeeze-up region extending up the semiconductor device a height;
curing the underfill material; and
removing the template.

9. The method of claim 8, wherein the underfill material pressing against the walls of the template causes the underfill material to have substantially planar exterior sides.

10. The method of claim 8, wherein the height of the squeeze-up region measures more than the thickness of the underfill material and less than or equal to a height of the semiconductor device.

11. The method of claim 8, wherein the squeeze-up region has a width, the width measuring up to 200 μm.

12. The method of claim 8, wherein disposing the template on the substrate comprises photolithography using a photoresist material.

13. The method of claim 8, wherein the template comprises metal or rubber.

14. The method of claim 8, wherein disposing the template on the substrate comprises spraying, screen printing, or inkjet printing.

15. The method of claim 8, wherein the template sidewalls have a height of up to 1 mm.

16. The method of claim 8, wherein the template sidewalls have a wall thickness between about 10 μm and about 250 μm.

17. The method of claim 8, wherein the template sidewalls have a Young's Modulus of at least 2.0 GPa.

18. The method of claim 8, further comprising:
disposing a stack of core semiconductor devices atop the semiconductor device, wherein each core semiconductor device has a layer of underfill material beneath it;
disposing a top semiconductor device atop the stack of core semiconductor devices, wherein the top semiconductor device has a layer of underfill material beneath it;
bonding the stack of core semiconductor devices and the top semiconductor device, causing each layer of underfill material to bulge beyond the device above it, making contact with the sidewalls of the template such that the layers of underfill material run together to form an underfill encasement surrounding the stack and a squeeze-up region extending up the top semiconductor device a distance; and
curing the layers of underfill material and the underfill encasement.

19. A method of making a semiconductor device assembly, the method comprising:
providing a semiconductor wafer;
forming a photoresist mask having a plurality of openings defined by sidewalls;
disposing a stack of semiconductor devices inside each opening of the plurality such that each stack is surrounded by the sidewalls, wherein each stack includes a top semiconductor device at the top of the stack, wherein each semiconductor device of each stack has an underfill material disposed in a gap underneath it, wherein the gap has a thickness, wherein each stack has a first height, wherein the photoresist mask has a second height, and wherein the first height is less than or equal to the second height;
pressing down on the top semiconductor device of each stack while increasing a temperature, causing the underfill material to squeeze out from the stack and form an underfill coating around the stack with a squeeze-up region that reaches a distance up the top semiconductor device;
curing the underfill material and underfill coating;
stripping the photoresist mask from the wafer; and
singulating the wafer into individual semiconductor device assemblies, each assembly including a cured underfill coating with a squeeze-up region.
